(19) United States
(12) Patent Application Publication
(10) Pub. No.: US 2016/0195889 A1
(43) Pub. Date: Jul. 7, 2016

(54) SEMICONDUCTOR DEVICE AND SEMICONDUCTOR SYSTEM INCLUDING A VOLTAGE DETECTION BLOCK

(71) Applicant: SK hynix Inc., Icheon-si Gyeonggi-do (KR)

(72) Inventor: Seung Han OK, Icheon-si Gyeonggi-do (KR)

(21) Appl. No.: 14/715,698

(22) Filed: May 19, 2015

(30) Foreign Application Priority Data
Jan. 5, 2015 (KR) 10-2015-0000488

(51) Int. Cl. G05F 3/02; H03K 17/687

(52) U.S. Cl. CPC G05F 3/02; H03K 17/687

(57) ABSTRACT

A semiconductor device may include an internal voltage generation circuit including at least one resistor element and a plurality of MOS transistors, and configured to change amounts of current flowing through the plurality of MOS transistors according to a level of the first node and control driving of an internal voltage. The semiconductor device may include an internal circuit configured to operate by being supplied with the internal voltage. The at least one resistor element is electrically coupled between the internal voltage and a first node. The plurality of MOS transistors are electrically coupled between the at least one resistor element and a power supply voltage.

### CROSS-REFERENCE TO RELATED APPLICATION

The present application claims priority under 35 U.S.C. §119(a) to Korean application number 10-2015-0000488, filed on Jan. 5, 2014, in the Korean Intellectual Property Office, which is incorporated herein by reference in its entirety.

### BACKGROUND

1. Technical Field

Embodiments of the present disclosure generally relate to a semiconductor device and a semiconductor system including a voltage detection block.

2. Related Art

In general, a semiconductor device is supplied with a power supply voltage (VDD) exteriorly from the semiconductor device. The semiconductor device is supplied with a ground voltage (VSS) from an exterior as well. With the power supply (VDD) voltage and ground voltage (VSS), the semiconductor device generates and uses internal voltages necessary for internal operations. Voltages necessary for the internal operations of a semiconductor device include a core voltage (VCORE), a boost voltage (VPP), and a back bias voltage (VBB). The core voltage (VCORE) is supplied to a memory core region. The boost voltage (VPP) is used for driving a word line or during overdriving. The back bias voltage (VBB) is supplied as the bulk voltage of an NMOS transistor in a core region.

The core voltage (VCORE) may be supplied at a predetermined level by reducing the power supply voltage (VDD) received from the exterior. However, the boost voltage (VPP) has a level higher than the power supply voltage (VDD) inputted from the exterior, and the back bias voltage (VBB) retains a level lower than the ground voltage (VSS) inputted from the exterior. Therefore, a charge pump circuit is needed to supply charges for the boost voltage (VPP) and the back bias voltage (VBB).

### SUMMARY

In an embodiment, a semiconductor device may include an internal voltage generation circuit including at least one resistor element and a plurality of MOS transistors, and configured to change amounts of current flowing through the plurality of MOS transistors according to a level of the first node and control driving of an internal voltage. The semiconductor device may include an internal circuit configured to operate by being supplied with the internal voltage. The at least one resistor element is electrically coupled between the internal voltage and a first node. The plurality of MOS transistors are electrically coupled between the at least one resistor element and a power supply voltage.

In an embodiment, a semiconductor system may include a first semiconductor device configured to apply a power supply voltage. The semiconductor system may include a second semiconductor device including an internal voltage generation circuit configured to receive the power supply voltage and to generate an internal voltage for operating an internal circuit. The internal voltage generation circuit may include at least one resistor element electrically coupled between the internal voltage and a first node and a plurality of MOS transistors, and may be configured to change amounts of current flowing through the plurality of MOS transistors according to a level of the first node and control driving of the internal voltage.

In an embodiment, a voltage detection block may include a resistor element electrically coupled between an internal voltage and a first node. The voltage detection block may include a first MOS transistor electrically coupled between the first node and a second node, the second node configured to output a pull-up signal, and the first MOS transistor may be configured to be turned on in response to a signal of a third node. The voltage detection block may include a second MOS transistor electrically coupled between the first node and a fourth node, and may be configured to be turned on in response to the signal of the third node. The voltage detection block may include a third MOS transistor electrically coupled between the fourth node and a fifth node, and may be configured to be turned on in response to the signal of the third node. The voltage detection block may include a fourth MOS transistor electrically coupled between the fifth node and a sixth node, and may be configured to be turned on in response to the signal of the third node. The voltage detection block may include a fifth MOS transistor electrically coupled between the sixth node and a power supply voltage, and may be configured to be turned on in response to a signal of the sixth node. The voltage detection block may include a sixth transistor electrically coupled between the second node and the power supply voltage, and may be configured to be turned on in response to the signal of the sixth node. The voltage detection block may include a pull-up driving unit configured to drive an output node in response to the pull-up signal.

### BRIEF DESCRIPTION OF THE DRAWINGS

FIG. 1 is a block diagram illustrating a representation of an example of the configuration of a semiconductor system in accordance with an embodiment.

FIG. 2 is a block diagram illustrating a representation of an example of the configuration of the internal voltage generation circuit included in the semiconductor system illustrated in FIG. 1, in accordance with an embodiment.

FIG. 3 is a circuit diagram illustrating a representation of an example of the voltage detection block included in the internal voltage generation circuit illustrated in FIG. 2, in accordance with an embodiment.

FIG. 4 is a circuit diagram illustrating a representation of an example of the voltage detection block included in the internal voltage generation circuit illustrated in FIG. 2, in accordance with an embodiment.

FIG. 5 is a circuit diagram illustrating a representation of an example of the configuration of the internal circuit included in the semiconductor system illustrated in FIG. 1, in accordance with an embodiment.

FIG. 6 illustrates a block diagram of an example of a representation of a general system employing the semiconductor device and/or semiconductor system in accordance with the embodiments discussed above with relation to FIGS. 1-5.

### DETAILED DESCRIPTION

Hereinafter, a semiconductor device and a semiconductor system including a voltage detection block will be described below with reference to the accompanying drawings through various examples of embodiments.

Various embodiments may be directed to a semiconductor device and a semiconductor system including a voltage detection block capable of stably generating an internal voltage.

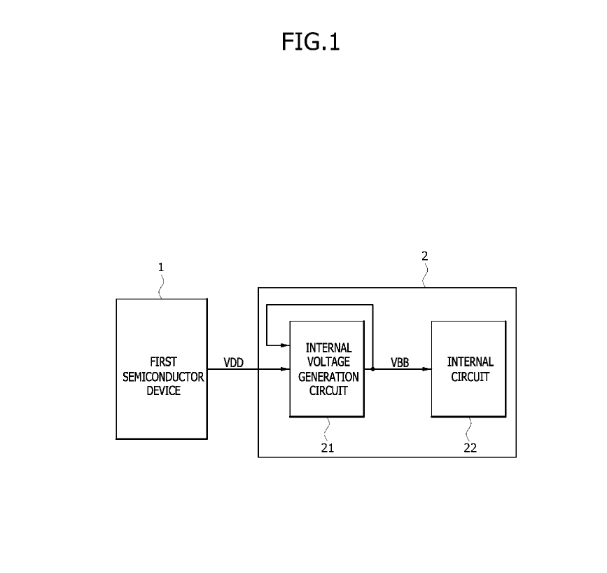

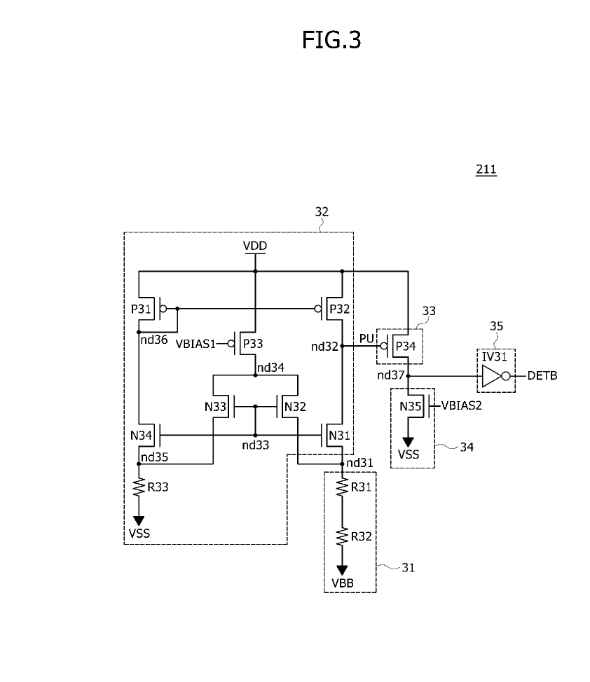

Referring to FIG. 1, a semiconductor system in accordance with an embodiment may include a first semiconductor device 1 and a second semiconductor device 2. The first semiconductor device 1 may apply a power supply voltage VDD to the second semiconductor device 2. The second semiconductor device 2 may include an internal voltage generation circuit 21 and an internal circuit 22. The internal voltage generation circuit 21 may operate by being supplied with the power supply voltage VDD. The internal voltage generation circuit 21 is fed back with an internal voltage VBB, set the level of a node nd31 (see FIG. 3) according to the level of the internal voltage VBB, and control the driving of the internal voltage VBB, according to the level of the node nd31. The internal circuit 22 may operate by being supplied with the internal voltage VBB generated in the internal voltage generation circuit 21.

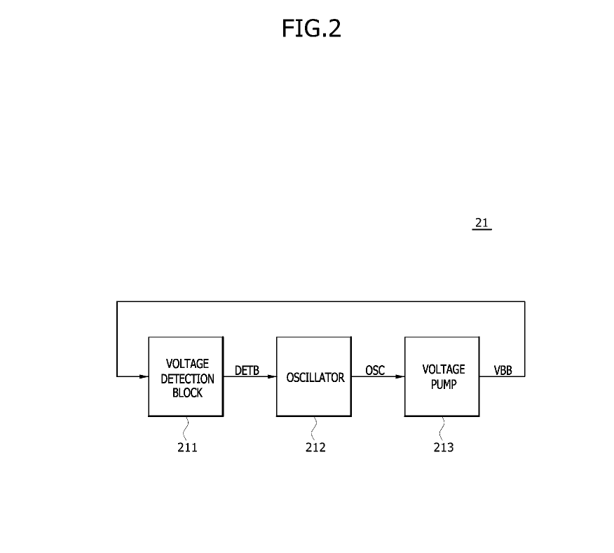

Referring to FIG. 2, the internal voltage generation circuit 21 may include a voltage detection block 211, an oscillator 212, and a voltage pump 213. The voltage detection block 211 may detect the level of the internal voltage VBB. The voltage detection block 211 may generate a detection signal DETB for controlling the driving of the internal voltage VBB. For example, the voltage detection block 211 may generate the detection signal DETB enabled (or at a predetermined level), when the level of the internal voltage VBB is a level higher than a target level. The oscillator 212 may generate an oscillation signal OSC when the enabled detection signal DETB is inputted. The voltage pump 213 may pump the internal voltage VBB and set the level of the internal voltage VBB to be low when the oscillation signal OSC is inputted.

Referring to FIG. 3, the voltage detection block 211 may include a level setting unit 31, a pull-up signal generation unit 32, and a pull-up driving unit 33. The voltage detection block 211 may include a pull-down driving unit 34, and a buffer unit 35. The level setting unit 31 may include resistor elements R31 and R32. The resistor elements R31 and R32 may be electrically coupled between the node nd31 and the internal voltage VBB. The level of the node nd31 may be controlled by the resistance values of the resistor elements R31 and R32. The pull-up signal generation unit 32 may include PMOS transistors P31, P32 and P33 and NMOS transistors N31, N32, N33 and N34. The NMOS transistor N31 may be electrically coupled between the node nd31 and a node nd32. The NMOS transistor N31 may be turned on in response to the level of a node nd33. The NMOS transistor N32 may be electrically coupled between the node nd31 and a node nd34. The NMOS transistor N32 may be turned on in response to the level of the node nd33. The NMOS transistor N33 may be electrically coupled between the node nd34 and a node nd35. The NMOS transistor N33 may be turned on in response to the level of the node nd33. The NMOS transistor N34 may be electrically coupled between the node nd35 and a node nd36. The NMOS transistor N34 may be turned on in response to the level of the node nd33. The PMOS transistor P31 may be electrically coupled between the node nd36 and the power supply voltage VDD. The PMOS transistor P31 may be turned on in response to the level of the node nd36. The PMOS transistor P32 may be electrically coupled between the node nd32 and the power supply voltage VDD. The PMOS transistor P32 may be turned on in response to the level of the node nd36. The PMOS transistor P33 may be electrically coupled between the node nd34 and the power supply voltage VDD. The PMOS transistor P33 may be turned on in response to a first bias voltage VBIAS1. The pull-up driving unit 33 may include a PMOS transistor P34. The pull-up driving unit 33 may pull-up drive a node nd37 with the power supply voltage VDD in response to a pull-up signal PU outputted from the node nd32. The pull-down driving unit 34 may include an NMOS transistor N35. The pull-down driving unit 34 may be turned on in response to a second bias voltage VBIAS2 and pull-down drive the node nd37 with a ground voltage VSS. The buffer unit 35 may be configured by an inverter IV31. The buffer unit 35 may invert and buffer the signal of the node nd37 and generate the detection signal DETB. The first bias voltage VBIAS1 may be generated at a level that will turn on the PMOS transistor P33. The second bias voltage VBIAS2 may be generated at a level that will turn on the NMOS transistor N35.

Since the level of the node nd31 falls as the level of the internal voltage VBB rises, the amounts of current flowing through the NMOS transistor N31 and the NMOS transistor N32 may increase, and the amounts of current flowing through the NMOS transistor N33 and the NMOS transistor N34 may decrease. Accordingly, since the level of the node nd36 rises and the amount of current flowing through the PMOS transistor P32 decreases, the level of the node nd32 may fall. In the example where the level of the internal voltage VBB becomes higher than the target level that is preset, the level of the node nd32 falls to a degree capable of turning on the PMOS transistor P34 included in the pull-up driving unit 33, and the node nd37 is pull-up driven with the power supply voltage VDD. Accordingly, the detection signal DETB outputted through the buffer unit 35 is enabled to a logic low level, and activates the oscillator 212 and the voltage pump 213 illustrated in FIG. 2 such that the level of the internal voltage VBB may fall.

Since the level of the node nd31 rises as the level of the internal voltage VBB falls, the amounts of current flowing through the NMOS transistor N31 and the NMOS transistor N32 may decrease, and the amounts of current flowing through the NMOS transistor N33 and the NMOS transistor N34 may increase. Accordingly, since the level of the node nd36 falls and the amount of current flowing through the PMOS transistor P32 increases, the level of the node nd32 may rise. The PMOS transistor P34 included in the pull-up driving unit 33 is turned off by the level of the node nd32 that has risen, and the node nd37 is pull-down driven with the ground voltage VSS. Accordingly, the detection signal DETB outputted through the buffer unit 35 is disabled to a logic high level, and deactivates the oscillator 212 and the voltage pump 213 illustrated in FIG. 2.

As described above, the voltage detection block 211 in accordance with an embodiment may set the level of the node nd31 according to the level of the internal voltage VBB, and may drive the detection signal DETB through the NMOS transistors N31 to N34 and the PMOS transistors P31 and P32 which are changed in their current amounts according to the level of the node nd31. Because the detection signal DETB for controlling the generation of the internal voltage VBB is generated without using a reference voltage, it may be possible to stably generate the internal voltage VBB even at a low level of the power supply voltage VDD.

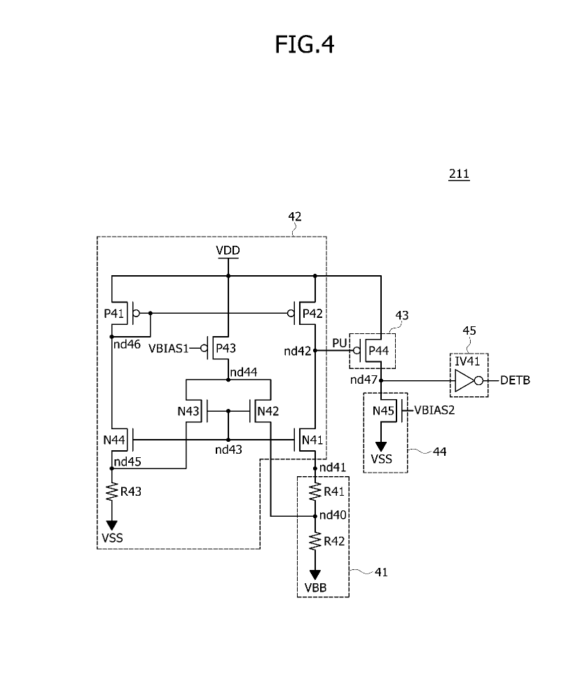

Referring to FIG. 4, the voltage detection block 211 may include a level setting unit 41, a pull-up signal generation unit 42, and a pull-up driving unit 43. The voltage detection block 211 may include a pull-down driving unit 44, and a buffer unit 45. The level setting unit 41 may include resistor elements R41 and R42. The resistor element R41 may be electrically coupled between a node nd40 and a node nd41. The resistor element R42 may be electrically coupled between the node nd40 and the internal voltage VBB. The level of the node nd40 may be controlled by the resistance values of the resistor elements R41 and R42. The pull-up signal generation unit 42 may include PMOS transistors P41, P42 and P43, and NMOS transistors N41, N42, N43 and N44. The NMOS transistor N41 may be electrically coupled between the node nd41 and a node nd42. The NMOS transistor N41 may be turned on in response to the level of a node nd43. The NMOS transistor N42 may be electrically coupled between the node nd40 and a node nd44. The NMOS transistor N42 may be turned on in response to the level of the node nd43. The NMOS transistor N43 may be electrically coupled between the node nd44 and a node nd45. The NMOS transistor N43 may be turned on in response to the level of the node nd43. The NMOS transistor N44 may be electrically coupled between the node nd45 and a node nd46. The NMOS transistor N44 may be turned on in response to the level of the node nd43. The PMOS transistor P41 may be electrically coupled between the node nd46 and the power supply voltage VDD. The PMOS transistor P41 may be turned on in response to the level of the node nd46. The PMOS transistor P42 may be electrically coupled between the node nd42 and the power supply voltage VDD. The PMOS transistor P42 may be turned on in response to the level of the node nd46. The PMOS transistor P43 may be electrically coupled between the node nd44 and the power supply voltage VDD. The PMOS transistor P43 may be turned on in response to a first bias voltage VBIAS1. The pull-up driving unit 43 may include a PMOS transistor P44. The pull-up driving unit 43 may pull-up drive a node nd47 with the power supply voltage VDD in response to a pull-up signal PU outputted from the node nd42. The pull-down driving unit 44 may include an NMOS transistor N45. The NMOS transistor N45 may be turned on in response to a second bias voltage VBIAS2 and the pull-down driving unit 44 may pull-down drive the node nd47 with a ground voltage VSS. The buffer unit 45 may be configured by an inverter IV41. The buffer unit 45 may invert and buffer the signal of the node nd47 and generate the detection signal DETB. The first bias voltage VBIAS1 may be generated at a level that will turn on the PMOS transistor P43. The second bias voltage VBIAS2 may be generated at a level that will turn on the NMOS transistor N45.

Since the level of the node nd40 falls as the level of the internal voltage VBB rises, the amount of current flowing through the NMOS transistor N41 and the NMOS transistor N42 increase, and the amounts of current flowing through the NMOS transistor N43 and the NMOS transistor N44 decrease. Accordingly, since the level of the node nd46 rises and the amount of current flow through the PMOS transistor P42 decreases the level of the node nd42 falls. In the example where the level of the internal voltage VBB becomes higher than the target level that is preset, the level of the node nd42 falls to a degree capable of turning on the PMOS transistor P44 included in the pull-up driving unit 43, and the node nd47 is pull-up driven with the power supply voltage VDD. Accordingly, the detection signal DETB outputted through the buffer unit 45 is enabled to a logic low level, and activates the oscillator 212 and the voltage pump 213 illustrated in FIG. 2 such that the level of the internal voltage VBB falls.

Since the level of the node nd40 rises as the level of the internal voltage VBB falls, the amounts of current flow through the NMOS transistor N41 and the NMOS transistor N42 decrease, and the amounts of current flow through the NMOS transistor N43 and the NMOS transistor N44 increase. Accordingly, since the level of the node nd46 falls and the amount of current flowing through the PMOS transistor P42 increases, the level of the node nd42 rises. The PMOS transistor P44 included in the pull-up driving unit 43 is turned off by the level of the node nd42 that has risen, and the node nd47 is pull-down driven with the ground voltage VSS. Accordingly, the detection signal DETB outputted through the buffer unit 45 is disabled to a logic high level, and deactivates the oscillator 212 and the voltage pump 213 illustrated in FIG. 2.

As described above, the voltage detection block 211 in accordance with an embodiment sets the level of the node nd40 according to the level of the internal voltage VBB, and drives the detection signal DETB through the NMOS transistors N41 to N44 and the PMOS transistors P41 and P42 which are changed in their current amounts according to the level of the node nd40. Because the detection signal DETB for controlling the generation of the internal voltage VBB is generated without using a reference voltage, it may be possible to stably generate the internal voltage VBB even at a low level of the power supply voltage VDD.

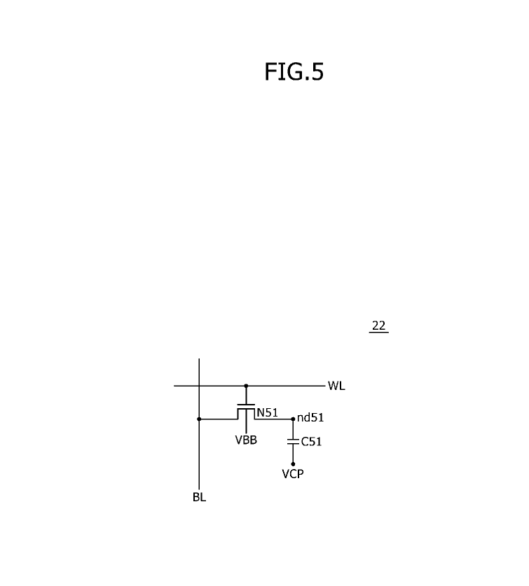

Referring to FIG. 5, the internal circuit 22 may include an NMOS transistor N51 and a capacitor C51. The NMOS transistor N51 may be electrically coupled between a bit line BL and a node nd51. The NMOS transistor N51 may operate as a cell transistor. The NMOS transistor N51 may be turned on in response to the level of a word line WL. The capacitor C51 may be electrically coupled between the node nd51 and a cell plate voltage VCP, and operate as a cell capacitor. The NMOS transistor N51 may be applied with the internal voltage VBB. The internal voltage VBB may be generated in the internal voltage generation circuit 21 illustrated in FIG. 1, as a back bias voltage. The threshold voltage of the NMOS transistor N51 is raised when the level of the internal voltage VBB is low, and is lowered when the level of the internal voltage VBB is high. Leakage current is set to be low, as the threshold voltage of the NMOS transistor N51 is high.

As is apparent from the above descriptions, according to the embodiments, since the driving of an internal voltage is determined according to an internal current amount that changes according to the level of the internal voltage, advantages may be provided in that it may be possible to stably generate the internal voltage even at a low level of a power supply voltage, without using a reference voltage.

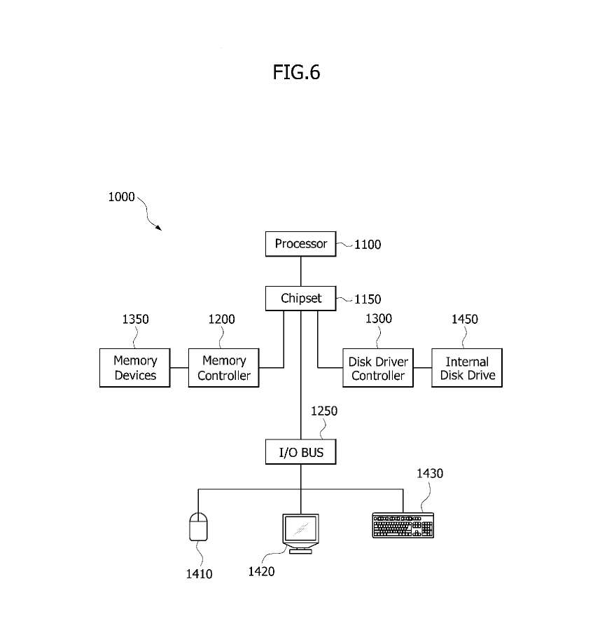

The semiconductor device and or semiconductor system discussed above (see FIGS. 1-5) are particular useful in the design of memory devices, processors, and computer systems. For example, referring to FIG. 6, a block diagram of a general system employing the semiconductor device and or semiconductor system in accordance with the embodiments are illustrated and generally designated by a reference numeral 1000. The general system 1000 may include one or more processors or central processing units (“CPUs”) 1100. The CPU 1100 may be used individually or in combination with other CPUs. While the CPU 1100 will be referred to primarily in the singular, it will be understood by those skilled in the art that a general system with any number of physical or logical CPUs may be implemented.

A chipset 1150 may be operably coupled to the CPU 1100. The chipset 1150 is a communication pathway for signals between the CPU 1100 and other components of the general system 1000, which may include a memory controller 1200, an input/output (“I/O”) bus 1250, and a disk drive controller 1300. Depending on the configuration of the general system, any one of a number of different signals may be transmitted through the chipset 1150, and those skilled in the art will appreciate that the routing of the signals throughout the general system 1000 can be readily adjusted without changing the underlying nature of the general system.

As stated above, the memory controller 1200 may be operably coupled to the chipset 1150. The memory controller 1200 may include at least one semiconductor device and or semiconductor system as discussed above with reference to FIGS. 1-5. Thus, the memory controller 1200 can receive a request provided from the CPU 1100, through the chipset 1150. In alternate embodiments, the memory controller 1200 may be integrated into the chipset 1150. The memory controller 1200 may be operably coupled to one or more memory devices 1350. In an embodiment, the memory devices 1350 may include the at least one semiconductor device and or semiconductor system as discussed above with relation to FIGS. 1-6, the memory devices 1350 may include a plurality of word lines and a plurality of bit lines for defining a plurality of memory cells. The memory devices 1350 may be any one of a number of industry standard memory types, including but not limited to, single inline memory modules (“SIMMs”) and dual inline memory modules (“DIMMs”). Further, the memory devices 1350 may facilitate the safe removal of the external data storage devices by storing both instructions and data.

The chipset 1150 may also be coupled to the I/O bus 1250. The I/O bus 1250 may serve as a communication pathway for signals from the chipset 1150 to I/O devices 1410, 1420 and 1430. The I/O devices 1410, 1420 and 1430 may include a mouse 1410, a video display 1420, or a keyboard 1430. The I/O bus 1250 may employ any one of a number of communications protocols to communicate with the I/O devices 1410, 1420, and 1430. Further, the I/O bus 1250 may be integrated into the chipset 1150.

The disk drive controller 1450 (i.e., internal disk drive) may also be operably coupled to the chipset 1150. The disk drive controller 1450 may serve as the communication pathway between the chipset 1150 and one or more internal disk drives 1450. The internal disk drive 1450 may facilitate disconnection of the external data storage devices by storing both instructions and data. The disk drive controller 1300 and the internal disk drives 1450 may communicate with each other or with the chipset 1150 using virtually any type of communication protocol, including all of those mentioned above with regard to the I/O bus 1250.

It is important to note that the general system 1000 described above in relation to FIG. 6 is merely one example of a general system employing the semiconductor device and or semiconductor system as discussed above with relation to FIGS. 1-5. In alternate embodiments, such as cellular phones or digital cameras, the components may differ from the embodiments illustrated in FIG. 6.

While various embodiments have been described above, it will be understood to those skilled in the art that the embodiments described are by way of example only. Accordingly, the semiconductor device and the semiconductor system including a voltage detection block described herein should not be limited based on the described embodiments.

What is claimed is:

1. A semiconductor device comprising:
an internal voltage generation circuit including at least one resistor element which is electrically coupled between an internal voltage and a first node and a plurality of MOS transistors, and configured to change amounts of current flowing through the plurality of MOS transistors according to a level of the first node and control driving of the internal voltage; and
an internal circuit configured to operate by being supplied with the internal voltage,
wherein the at least one resistor element is, and
wherein the plurality of MOS transistors are electrically coupled between the at least one resistor element and a power supply voltage.

2. The semiconductor device according to claim 1, wherein the internal voltage generation circuit comprises a voltage detection block configured to detect a level of the internal voltage and generate a detection signal for controlling the driving of the internal voltage.

3. The semiconductor device according to claim 2, wherein the voltage detection block comprises:
a resistor element electrically coupled between the internal voltage and the first node;
a pull-up signal generation unit electrically coupled to the first node, including the plurality of MOS transistors, and configured to generate a pull-up signal; and
a pull-up driving unit configured to drive an output node in response to the pull-up signal.

4. The semiconductor device according to claim 3, wherein the pull-up signal generation unit comprises:
a first MOS transistor electrically coupled between the first node and a second node from which the pull-up signal is outputted, and configured to be turned on in response to a signal of a third node; and
a second MOS transistor electrically coupled between the first node and a fourth node, and configured to be turned on in response to the signal of the third node.

5. The semiconductor device according to claim 4, wherein amounts of current flowing through the first and second MOS transistors increase as the level of the first node decreases.

6. The semiconductor device according to claim 4, wherein the pull-up signal generation unit further comprises:
a third MOS transistor electrically coupled between the fourth node and a fifth node, and configured to be turned on in response to the signal of the third node; and
a fourth MOS transistor electrically coupled between the fifth node and a sixth node, and configured to be turned on in response to the signal of the third node.

7. The semiconductor device according to claim 6, wherein amounts of current flowing through the third and fourth MOS transistors decrease as the level of the first node decreases.

8. The semiconductor device according to claim 6, wherein the pull-up signal generation unit further comprises:
a fifth MOS transistor electrically coupled between the sixth node and the power supply voltage, and configured to be turned on in response to a signal of the sixth node; and
a sixth transistor electrically coupled between the second node and the power supply voltage, and configured to be turned on in response to the signal of the sixth node.

9. The semiconductor device according to claim 8, wherein amounts of current flowing through the fifth and sixth MOS transistors decrease as the level of the first node decreases.

10. The semiconductor device according to claim 8, wherein the pull-up signal generation unit further comprises:
a seventh MOS transistor electrically coupled between the fourth node and the power supply voltage, and configured to be turned on in response to another bias voltage different from the bias voltage.

11. The semiconductor device according to claim 10,
wherein the first, second, third, and fourth MOS transistors are realized by NMOS transistors, and
wherein the fifth, sixth, and seventh MOS transistors are realized by PMOS transistors.

12. The semiconductor device according to claim 8, wherein the pull-up driving unit includes a MOS transistor coupled between the output node and the sixth MOS transistor and configured to receive the pull-up signal through a gate.

13. The semiconductor device according to claim 4, wherein the voltage detection block further comprises:
another resistor coupled between the first node and the first MOS transistor.

14. The semiconductor device according to claim 3, wherein the voltage detection block further comprises:
a pull-down driving unit configured to pull-down drive the output node in response to a bias voltage; and
a buffer unit configured to buffer a signal of the output node and generate the detection signal.

15. The semiconductor device according to claim 2, wherein the internal voltage generation circuit further comprises:
an oscillator configured to generate an oscillation signal in response to the detection signal; and
a voltage pump configured to pump the internal voltage when the oscillation signal is generated.

16. A semiconductor system comprising:
a first semiconductor device configured to apply a power supply voltage; and
a second semiconductor device including an internal voltage generation circuit, the internal voltage generation circuit configured to receive the power supply voltage and generate an internal voltage for operating an internal circuit,
wherein the internal voltage generation circuit includes at least one resistor element which is electrically coupled between the internal voltage and a first node and a plurality of MOS transistors, and configured to change amounts of current flowing through the plurality of MOS transistors according to a level of the first node and control driving of the internal voltage.

17. The semiconductor system according to claim 16, wherein the internal voltage generation circuit comprises a voltage detection block configured to detect a level of the internal voltage and generate a detection signal for controlling the driving of the internal voltage.

18. The semiconductor system according to claim 17, wherein the voltage detection block comprises:
a resistor element electrically coupled between the internal voltage and the first node;
a pull-up signal generation unit electrically coupled to the first node, including the plurality of MOS transistors, and configured to generate a pull-up signal; and
a pull-up driving unit configured to drive an output node in response to the pull-up signal.

19. The semiconductor system according to claim 18, wherein the pull-up signal generation unit comprises:
a first MOS transistor electrically coupled between the first node and a second node from which the pull-up signal is outputted, and configured to be turned on in response to a signal of a third node; and
a second MOS transistor electrically coupled between the first node and a fourth node, and configured to be turned on in response to the signal of the third node.

20. The semiconductor system according to claim 19, wherein amounts of current flowing through the first and second MOS transistors increase as the level of the first node decreases.

21. The semiconductor system according to claim 19, wherein the pull-up signal generation unit further comprises:
a third MOS transistor electrically coupled between the fourth node and a fifth node, and configured to be turned on in response to the signal of the third node;
a fourth MOS transistor electrically coupled between the fifth node and a sixth node, and configured to be turned on in response to the signal of the third node;
a fifth MOS transistor electrically coupled between the sixth node and the power supply voltage, and configured to be turned on in response to a signal of the sixth node; and
a sixth transistor electrically coupled between the second node and the power supply voltage, and configured to be turned on in response to the signal of the sixth node.

22. The semiconductor device according to claim 21, wherein the pull-up signal generation unit further comprises:
a seventh MOS transistor electrically coupled between the fourth node and the power supply voltage, and configured to be turned on in response to another bias voltage different from the bias voltage.

23. The semiconductor device according to claim 22,
wherein the first, second, third, and fourth MOS transistors are realized by NMOS transistors, and
wherein the fifth, sixth, and seventh MOS transistors are realized by PMOS transistors.

24. The semiconductor device according to claim 21, wherein the pull-up driving unit includes a MOS transistor coupled between the output node and the sixth MOS transistor and configured to receive the pull-up signal through a gate.

25. The semiconductor device according to claim 19, wherein the voltage detection block further comprises:
another resistor coupled between the first node and the first MOS transistor.

26. The semiconductor system according to claim 21, wherein amounts of current flowing through the third and fourth MOS transistors decrease as the level of the first node decreases, and amounts of current flowing through the fifth and sixth MOS transistors decrease as the level of the first node decreases.

27. A voltage detection block comprising:
a resistor element electrically coupled between an internal voltage and a first node;
a first MOS transistor electrically coupled between the first node and a second node, the second node configured to output a pull-up signal, and the first MOS transistor configured to be turned on in response to a signal of a third node;
a second MOS transistor electrically coupled between the first node and a fourth node, and configured to be turned on in response to the signal of the third node;
a third MOS transistor electrically coupled between the fourth node and a fifth node, and configured to be turned on in response to the signal of the third node;
a fourth MOS transistor electrically coupled between the fifth node and a sixth node, and configured to be turned on in response to the signal of the third node;
a fifth MOS transistor electrically coupled between the sixth node and a power supply voltage, and configured to be turned on in response to a signal of the sixth node;
a sixth transistor electrically coupled between the second node and the power supply voltage, and configured to be turned on in response to the signal of the sixth node; and
a pull-up driving unit configured to drive an output node in response to the pull-up signal.

28. The voltage detection block according to claim 19, wherein amounts of current flowing through the first and second MOS transistors increase as the level of the first node decreases, amounts of current flowing through the third and fourth MOS transistors decrease as the level of the first node decreases, and amounts of current flowing through the fifth and sixth MOS transistors decrease as the level of the first node decreases.
